(19) United States
(12) Patent Application Publication
(10) Pub. No.: US 2009/0200067 A1
(43) Pub. Date: Aug. 13, 2009

(54) WIRING SUBSTRATE FOR ELECTRONIC-COMPONENT INSPECTION APPARATUS

(75) Inventor: Kazuya Nozu, San Jose, CA (US)

Correspondence Address: SUGHRUE MION, PLLC, 2100 PENNSYLVANIA AVENUE, N.W., SUITE 800, WASHINGTON, DC, 20037, US

(73) Assignee: NGK SPARK PLUG CO., LTD., Nagoya (JP)

(21) Appl. No.: 12/364,174

(22) Filed: Feb. 2, 2009

(30) Foreign Application Priority Data
Feb. 4, 2008 (JP) 2008-23722

(51) Int. Cl. H05K 1/03

(52) U.S. Cl. 174/255

(57) ABSTRACT

A wiring substrate K for an electronic-component inspection apparatus includes a substrate body (1) composed of a plurality of stacked ceramic layers s1 to s8 and having a front surface (2) and a back surface (3); and front-surface terminal electrodes f formed on the front surface (2) of the substrate body (1). Unit inspection patterns a1, individual ones of which are constituted by a plurality of the front-surface terminal electrodes f disposed to correspond to a plurality of terminal electrodes m of a single electronic component cn to be inspected, are regularly disposed in vertical and horizontal directions as viewed from above such that the centroids g of the unit inspection patterns a1 coincide with alternate ones of intersections j between vertical imaginary lines L1 to L3 and horizontal imaginary lines N1 to N4 passing through the centroids g of the unit inspection patterns a1.

### BACKGROUND OF THE INVENTION

1. Field of the Invention

The present invention relates to a wiring substrate for an electronic-component inspection apparatus which simultaneously inspects electrical characteristics of a plurality of electronic components with high accuracy.

2. Description of the Related Art

In order to simultaneously inspect the electrical characteristics of a large number of electronic components formed, for example, along a surface of an Si wafer, a probe assembly (see, for example, Patent Document 1) has been proposed which assumes, as a whole, a disk-like shape resembling the shape of the Si wafer. Therein, unit inspection patterns are continuously disposed on one surface of the assembly such that they are located adjacent to one another in two directions orthogonal to each other. The layout of the unit inspection patterns corresponds to a layout of the electronic components which are continuously disposed on the Si wafer such that they are located adjacent to one another in the two directions. A plurality of probes for inspecting individual electronic components are provided in each of the unit inspection patterns.

[Patent Document 1] Japanese Patent Application Laid-Open (kokai) No. 2007-3334 (Pages 1 to 11 and FIGS. 1 to 7)

However, in the case where unit inspection patterns, each used for inspecting a single electronic component, are continuously disposed such that they are located adjacent to one another in two orthogonal directions as in the probe assembly of Patent Document 1, the space between one unit inspection pattern and another unit inspection pattern adjacent thereto is narrow. Further, with an increasing number of terminals of each electronic component, the density of inspection pads to which probes are attached increases, so that the interval between adjacent inspection pads decreases.

Therefore, although the inspection pads to which probes are attached can be reduced in diameter within each unit inspection pattern, cover pads cannot be increased in size. The cover pads are formed separately from the inspection pads having a reduced diameter and establish electrical connection between the inspection pads and via conductors inside a ceramic substrate.

Further, in the case where the probe assembly is formed of a ceramic substrate, control of position accuracy of the inspection pads becomes difficult in a firing process. This is because shrinkage during the firing increases in a peripheral portion of the ceramic substrate, as compared with a central portion thereof. As a result, it has been difficult to provide a wiring substrate for an electronic-component inspection apparatus for simultaneously inspecting a large number of electronic components with high accuracy.

### SUMMARY OF THE INVENTION

It is therefore an object of the present invention to provide a wiring substrate for an electronic-component inspection apparatus for simultaneously and accurately inspecting the electrical characteristics of a plurality of electronic components formed on, for example, the surface of an Si wafer.

The present invention was accomplished based on the idea of shifting the unit inspection patterns, each used for inspecting a single electronic component to be inspected, in at least one of first and second directions orthogonal to each other.

That is, in a first aspect, the present invention provides a wiring substrate for an electronic-component inspection apparatus which comprises a substrate body composed of a plurality of stacked ceramic layers, said substrate body having a front surface and a back surface; and front-surface terminal electrodes formed on the front surface of the substrate body and grouped into unit inspection patterns, individual ones of the unit inspection patterns being constituted by a plurality of the front-surface terminal electrodes disposed so as to correspond to a plurality of terminal electrodes of individual electronic components to be inspected, wherein said unit inspection patterns are disposed so as to be offset distance-wise from a lattice arrangement or matrix in at least one of orthogonal first and second directions, as viewed from above the front surface of the substrate body. The amount of the shift is smaller than the size of the unit inspection patterns.

Further, a second wiring substrate for an electronic-component inspection apparatus according to a second aspect of the present invention comprises a substrate body composed of a plurality of stacked ceramic layers, said substrate body having a front surface and a back surface; and front-surface terminal electrodes formed on the front surface of the substrate body and grouped into unit inspection patterns, individual ones of the unit inspection patterns being constituted by a plurality of the front-surface terminal electrodes disposed so as to correspond to a plurality of terminal electrodes of individual electronic components to be inspected, wherein said unit inspection patterns are disposed so as to be offset distance-wise from a lattice arrangement of rows and columns in at least one of orthogonal first and second directions, as viewed from above the front surface of the substrate body, such that the unit inspection patterns are arranged in every other row but not in alternate rows in at least one of the first and second directions.

Further, a third wiring substrate for an electronic-component inspection apparatus according to a third aspect of the present invention comprises a substrate body composed of a plurality of stacked ceramic layers, said substrate body having a front surface and a back surface; and front-surface terminal electrodes formed on the front surface of the substrate body, and grouped into unit inspection patterns, individual ones of the unit inspection patterns being constituted by a plurality of the front-surface terminal electrodes disposed so as to correspond to a plurality of terminal electrodes of individual electronic components to be inspected, wherein said unit inspection patterns are regularly arranged in orthogonal first and second directions, as viewed from above the front surface of the substrate body, such that centroids of the respective unit inspection patterns coincide with alternate ones of intersections between first imaginary lines and second imaginary lines extending along the first and second directions, respectively, and passing through the centroids of the unit inspection patterns. The intervals of the first imaginary lines in the first direction or the intervals of the second imaginary lines in the second direction are equal to or greater than the size of the unit inspection patterns as measured along the same direction.

By virtue of these configurations, on the surface of the substrate body, the plurality of unit inspection patterns are disposed while being offset distance-wise from a lattice arrangement in at least one of the first and second directions, as viewed from above; or are disposed while being offset distance-wise from a lattice arrangement in at least one of orthogonal first and second directions, as viewed from above the front surface of the substrate body, such that the unit inspection patterns are arranged in every other row (but not in alternate rows) in at least one of the first and second directions. Alternatively, the plurality of unit inspection patterns are regularly arranged in orthogonal first and second directions, as viewed from above the front surface of the substrate body, such that the centroids of the respective unit inspection patterns coincide with (and only with) alternate ones of intersections between first imaginary lines and second imaginary lines extending along the first and second directions, respectively, and passing through the centroids of the unit inspection patterns (e.g., a checkered pattern, or the surface pattern of a chess board). As a result, a surface where no unit inspection pattern is present exists between adjacent unit inspection patterns.

Therefore, even in the case where, in individual ones of the unit inspection patterns, inspection pads which constitute front-surface terminal electrodes and to which probes are attached are reduced in diameter, or the interval between adjacent inspection pads is decreased, cover pads which are connected to the inspection pads via connection wiring traces and which are also connected to via conductors within the substrate body can be disposed, while having an increased size.

Moreover, in the case where the plurality of unit inspection patterns are arranged on the front surface of the substrate body composed of a plurality of ceramic layers in a manner as described above, large cover pads can be formed on the surfaces between the unit inspection patterns as described above. In this manner, shrinkage control at the time of manufacture of the wiring substrate is facilitated, even if shrinkage of the substrate body during firing influences position accuracy to a greater degree in a peripheral portion of the substrate body, as compared with a central portion thereof.

Accordingly, the wiring substrates for an electronic-component inspection apparatus according to the present invention enable simultaneous and accurate inspection of electrical characteristics of a plurality of electronic components formed on, for example, a Si wafer. Of all the electronic components located adjacent to one another in the orthogonal first and second directions, the electronic components to be inspected simultaneously form, for example, groups in which the electronic components form rows which are located at every other row position in the first or second directions, or groups in which the electronic components are located at every other pattern position in the first and second directions.

The ceramic layers are formed of a high-temperature-fired ceramic (e.g., alumina) or a low-temperature-fired ceramic (e.g., glass ceramic).

Individual ones of the front-surface terminal electrodes include, for example, a laminate composed of a Ti thin film layer, a Ni thin film layer and a Cu plating layer; and Ni and Au plating layers which cover the entire surface of the laminate.

Further, the unit inspection patterns are formed by a plurality of inspection pads described below, which are disposed on the front surface of the substrate body such that they correspond to a plurality of terminal electrodes of individual electronic components to be inspected (device to be inspected) and which constitute a plurality of the front-surface terminal electrodes.

In addition, the centroid of the unit inspection pattern may be the centroid of a rectangle formed by tangential lines which are tangent to outermost portions of a plurality of inspection pads constituting the plurality of front-surface terminal electrodes, which constitute a single unit inspection pattern.

In a preferred embodiment, the present invention encompasses a wiring substrate for an electronic-component inspection apparatus in which some of the front-surface terminal electrodes each includes at least an inspection pad formed inside an associated unit inspection pattern, a cover pad connected to a via conductor exposed to the front surface of the substrate body, and a connection wiring trace which connects the inspection pad and the cover pad.

Since a surface where no unit inspection pattern is present is provided between adjacent unit inspection patterns, it is possible to form the inspection pads, which constitute the front-surface terminal electrodes, inside an associated unit inspection pattern; form the cover pads on the surface outside the unit inspection pattern; and form the connection wiring traces between the inspection pads and the cover pads across the boundary of the unit inspection pattern. Therefore, supply of electricity to the inspection pads and transmission of inspection signals from the terminal electrodes of each electronic component to be inspected can be performed accurately and reliably.

Notably, the front-surface terminal electrodes may be formed such that all of the inspection pads, cover pads, and connection wiring traces are formed within an associated unit inspection pattern, or may be composed of only an inspection pad connected directly to a corresponding via conductor.

Individual ones of the inspection pad, the cover pad, and the connection wiring trace include a laminate which is formed on a polished surface and which is composed of a Ti thin film layer, an Ni thin film layer, and a Cu plating layer; and Ni and Au plating layers plated over the entire surface of the laminate.

Further, in yet another preferred embodiment, the present invention encompasses a wiring substrate for an electronic-component inspection apparatus in which individual ones of the unit inspection patterns have a rectangular shape as viewed from above the front surface of the substrate body; a plurality of inspection pads are formed along all sides of respective unit inspection patterns; cover pads individually connected to the inspection pads via dedicated connection wiring traces are formed in an area surrounded by the inspection pads associated with a unit inspection pattern or outside an associated unit inspection pattern; and the cover pads are connected to via conductors which pass through at least an uppermost ceramic layer which forms the front surface of the substrate body.

This configuration enables easy formation of inspection pads along each side of individual ones of the unit inspection patterns so as to be located inside an associated pattern, easy formation of large cover pads on the surface located outside the unit inspection pattern and between that unit inspection pattern and an adjacent unit inspection pattern, and easy formation of connection wiring traces between the inspection pads and the cover pads across the boundary of the unit inspection pattern.

Further, in yet another preferred embodiment, the present invention encompasses a wiring substrate for an electronic-component inspection apparatus in which the cover pads are larger than the inspection pads.

By virtue of this configuration, even when the inspection pads in the unit inspection pattern are reduced in diameter, supply of electricity to the inspection pads and transmission of inspection signals from each electronic component to be inspected can be performed accurately and reliably. This is because the via conductors are electrically connected to the inspection pads via the cover pads which are larger in size than the inspection pads,

Moreover, in yet another preferred embodiment, the present invention encompasses a wiring substrate for an electronic-component inspection apparatus in which the cover pads are larger in diameter than the via conductors to which the cover pads are connected.

By virtue of this configuration, the via conductors can be readily connected to cover pads having a larger diameter. Therefore, even when the substrate body formed of a plurality of ceramic layers is influenced by firing shrinkage during manufacture thereof, electrical connection between the cover pads and the via conductors and between the via conductors and the inspection pads via the cover pads can be reliably established.

In addition, in yet another preferred embodiment, the present invention encompasses a wiring substrate for an electronic-component inspection apparatus in which the diameter of the cover pads is at least 2.5 times the diameter of the via conductors.

By virtue of this configuration, the via conductors can be reliably and readily connected to cover pads having a larger diameter.

Notably, when the diameter of the cover pads is less than 2.5 times the diameter of the via conductors, the wiring substrate becomes more likely to be influenced by firing shrinkage during manufacture thereof. Therefore, this range is excluded in this preferred embodiment. Although the upper limit is not defined for the ratio of the diameter of the cover pads to the diameter of the via conductors, the maximum ratio is preferably set to about 4 in order to secure an appropriate clearance between adjacent cover pads.

### BRIEF DESCRIPTION OF THE DRAWINGS

FIG. 1 is a cross-sectional view showing, among others, a main portion of the first through third wiring substrates according to the present invention.

FIG. 2 is a plan view showing a portion of the front surface of the third wiring substrate.

FIG. 3 is a schematic enlarged view of a portion of FIG. 2.

FIG. 4 is a partial cross-sectional view taken along the line X-X in FIG. 3.

FIG. 5 is a partial schematic view showing a portion of an object to be inspected by use of the third wiring substrate.

FIG. 6 is a partial schematic view showing a step for inspecting the object by use of the third wiring substrate.

FIG. 7 is a partial schematic view showing a step subsequent to the step of FIG. 6 for inspecting the object.

FIG. 8 is a schematic plan view showing a mode of arrangement of unit inspection patterns on the second wiring substrate.

FIG. 9 is a schematic plan view showing a different mode of arrangement of unit inspection patterns on the second wiring substrate.

FIG. 10 is a schematic plan view showing another different mode of arrangement of unit inspection patterns on the second wiring substrate.

FIG. 11 is a schematic plan view showing a mode of arrangement of unit inspection patterns on the first wiring substrate.

FIG. 12 is a schematic plan view showing a different mode of arrangement of unit inspection patterns on the first wiring substrate.

FIG. 13 is a schematic plan view showing another different mode of arrangement of unit inspection patterns on the first wiring substrate.

### DESCRIPTION OF REFERENCE NUMERALS

Reference numerals used to identify various structural features in the drawings include the following.
K: wiring substrate for an electronic-component inspection apparatus
1: substrate body
2: front surface
3: back surface
4: connection wiring trace
s1 to s8: ceramic layer
a1: unit inspection pattern
f: front-surface terminal electrode
p: inspection pad
cp: cover pad
v: via conductor
cn: electronic component to be inspected
m: terminal electrode
g: centroid
L1-L3, N1-N4: imaginary line
j: intersection
d1, d2, d3: diameter

### DETAILED DESCRIPTION OF THE INVENTION

The invention is next described in detail by reference to the drawings. However, the present invention should not be construed as being limited thereto.

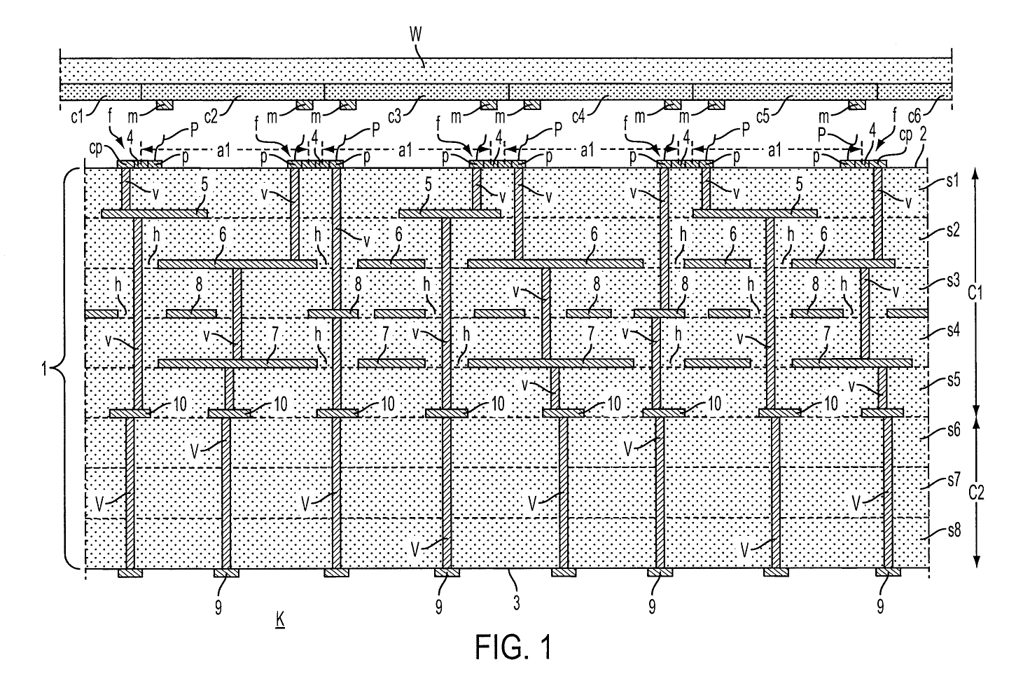

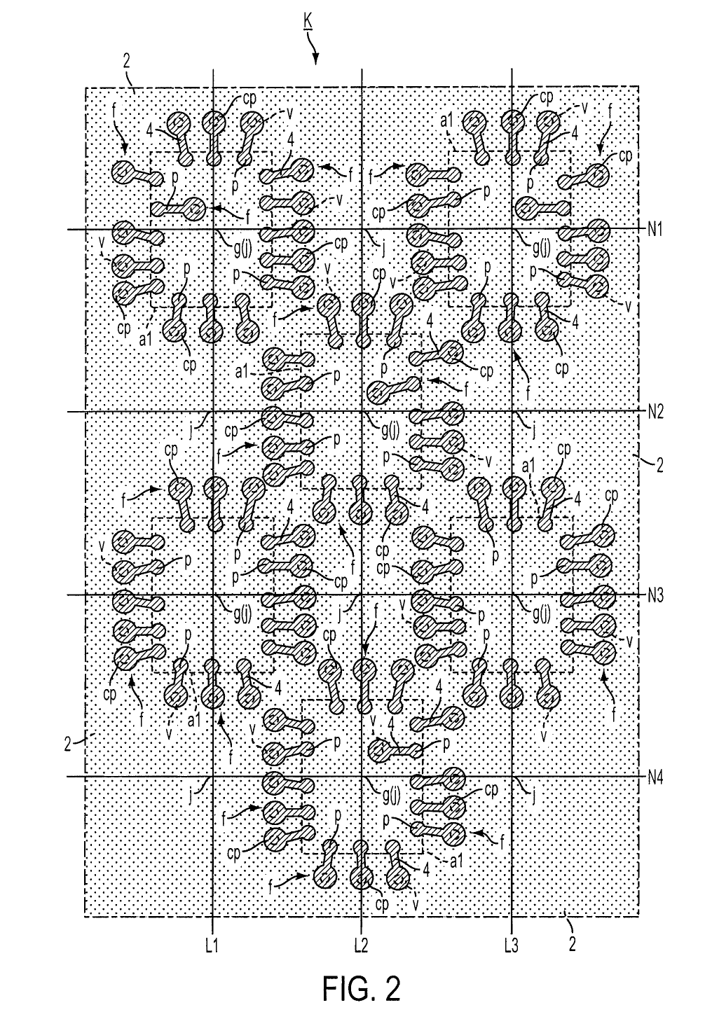

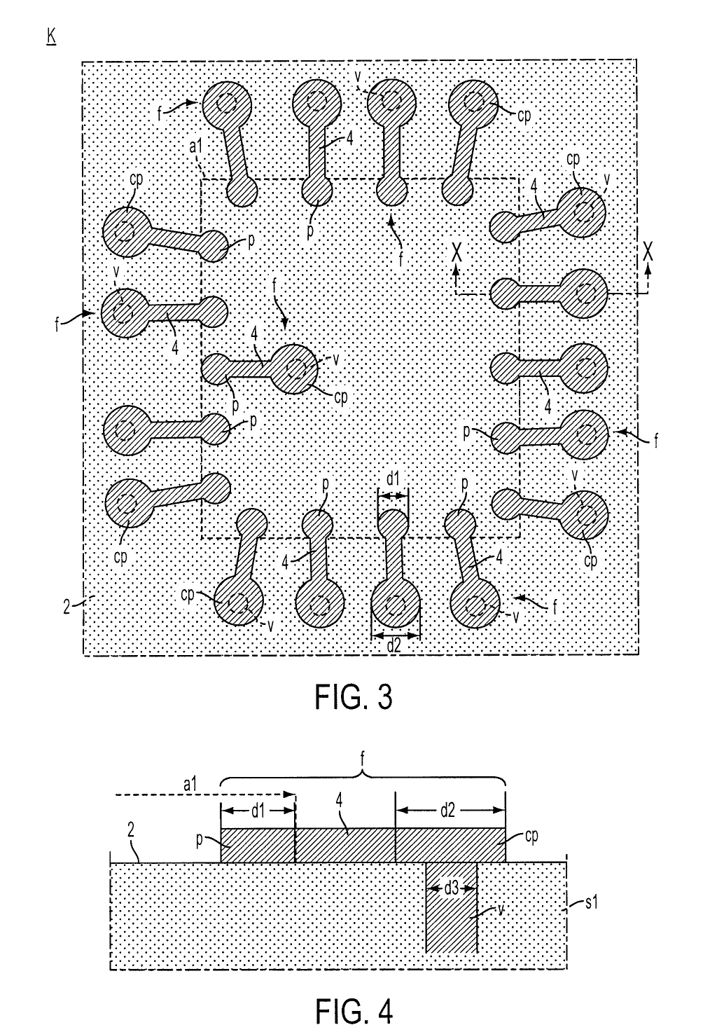

FIG. 1 is a sectional view showing a portion of an Si wafer W to be inspected, and a main portion of a wiring substrate for an electronic-component inspection apparatus (hereinafter also referred to as a “wiring substrate”) K, the structure being common among first through third wiring substrates of the present invention. FIG. 2 is a plan view showing a portion of a front surface 2 of a third wiring substrate K. FIG. 3 is an enlarged view of a portion of FIG. 2. As shown in FIGS. 1 and 2, the wiring substrate K includes a substrate body 1 composed of a plurality of stacked ceramic layers s1 to s8 and having the front surface 2 and a back surface 3; and a plurality of front-surface terminal electrodes f formed on the front surface 2 of the substrate body 1.

As shown in FIG. 1, the substrate body 1 is composed of a first laminate C1 including ceramic layers s1 to s5, and a second laminate C2 located below the first laminate C1 and including ceramic layers s6 to s8. A wiring layer 5 for power supply, a pair of wiring layers 6 and 7 for grounding, and a wiring layer 8 for signals, which are disposed therebetween, are formed between the ceramic layers s1 to s5 of the first laminate C1. Electrical conductivity is established between the wiring layers 5 to 8 and cover pads cp of the front-surface terminal electrodes f through via conductors v, which pass through the ceramic layers s1 to s5 including through-holes h allowing for passage of the via conductors v through the wiring layers 5 to 8.

Meanwhile, continuous, relatively long via conductors V pass through the ceramic layers s6 to s8 of the second laminate C2, and are connected to back surface electrodes 9 formed on the back surface 3. Lands 10 having a large diameter for connecting both the via conductors v and V are disposed between the ceramic layers s5 and s6; i.e., at the interface between the first laminate C1 and second laminate C2.

Notably, the ceramic layers s1 to s8 are formed of a high-temperature-fired ceramic (e.g., alumina) or a low-temperature-fired ceramic (e.g., glass ceramic). W, Mo, Ag, Cu, or the like is used for the wiring layers 5 to 8, the via conductors v and V, and the lands 10, depending on the kind of the ceramic.

As shown in FIGS. 1 and 2, the Si wafer W to be inspected is placed on the front surface 2 of the substrate body 1. A large number of electronic components (e.g., IC chips) c1 to cn are formed on a surface of the Si wafer W such that they are located adjacent to one another in vertical and horizontal directions. In order to correspond to a plurality of terminal electrodes m of each electronic component cn to be inspected, front-surface terminal electrodes f which are identical in number with the terminal electrodes m are disposed on the front surface 2 of the substrate body 1. Unit inspection patterns a1, each composed of these front-surface terminal electrodes f, are disposed on the front surface 2.

Notably, the rectangular broken line in FIGS. 2 and 3, which define the unit inspection patterns a1, are imaginary lines which form a rectangular shape as viewed from above the front surface of the substrate body. The imaginary lines correspond to tangential lines which are tangent to outermost portions of a plurality of inspection pads p which constitute the front-surface terminal electrodes f. The imaginary lines form a generally rectangular frame as viewed from above.

As shown in FIGS. 2 and 3, the front-surface terminal electrodes f are formed along respective sides of the unit inspection patterns a1. Individual ones of the front-surface terminal electrodes f include an inspection pad p to which a probe P is to be attached, a cover pad cp, and a connection wiring trace 4 which connects the pads p and the cover pads cp. The cover pad cp is formed on an outer or inner side of an associated inspection pattern a1, and is connected to a corresponding via conductor v passing through at least the uppermost ceramic layer s1 including the first laminate C1.

Although not illustrated, some front-surface terminal electrodes f are formed only of an inspection pad p connected directly to a corresponding via conductor v. Individual ones of the front-surface terminal electrodes f, comprising the inspection pad p, the connection wiring trace 4, and the cover pad cp, are constituted by a Ti thin film layer formed on the front surface 2 having been polished flat and an Ni thin film layer; a Cu plating layer formed thereon; and Ni and Au plating layers which cover the entire surface thereof.

As shown in FIG. 1, the inspection pads p of the front-surface terminal electrodes f can be electrically connected to the terminal electrodes m of a corresponding electronic component cn (i.e., one of c1, c2, c3, etc.) via the probes P, which later are attached to the inspection pads p.

As shown in FIG. 2, the unit inspection patterns a1 each composed of a plurality of the front-surface terminal electrodes f are arranged on the front surface 2 of the third wiring substrate K as follows. In FIG. 2, imaginary lines L1 to L3 extending along a vertical direction are formed at intervals greater than the length of the shorter sides of the unit inspection patterns a1, and imaginary lines N1 to N4 extending along a horizontal direction are formed at intervals greater than the length of the longer sides of the unit inspection patterns a1. As viewed from above, the plurality of unit inspection patterns a1 of the front surface 2 are regularly disposed in the vertical and horizontal directions such that the centroids (centers) g of the unit inspection patterns a1 coincide with alternate intersections j between the imaginary lines Ln and Nn.

In other words, the plurality of unit inspection patterns a1 are disposed along the vertical and horizontal directions of the front surface 2 of the third wiring substrate K such that vertically adjacent unit inspection patterns a1 are separated from each other in the vertical direction by a distance greater than the length (the longer sides) of the unit inspection patterns a1, and horizontally adjacent unit inspection patterns a1 are separated from each other in the horizontal direction by a distance greater than the width (the shorter sides) of the unit inspection patterns a1; i.e., the unit inspection patterns a1 are disposed such that they are shifted from one another in the vertical and horizontal directions.

As shown in FIG. 2, the plurality of unit inspection patterns a1 are disposed along the vertical and horizontal directions such that a space generally corresponding to a single unit inspection pattern a1 is provided between adjacent unit inspection patterns a1. Therefore, even in the case where the plurality of inspection pads p, which constitute the front-surface terminal electrodes f, are disposed along the sides of the respective patterns a1 so as to be located on the inner side thereof as illustrated in an enlarged partial view of FIG. 3, the inspection pads p are reliably connected to the cover pads cp having a larger diameter via the dedicated wiring traces 4. The cover pads cp are disposed along the sides of the respective patterns also as to be located on an outer side thereof.

Notably, as shown in FIG. 2, some of the front-surface terminal electrodes f may be configured such that all of the inspection pads p, wiring traces 4, and cover pads cp of the individual front-surface terminal electrode f are located on the inner side of the unit inspection pattern a1. Alternatively, some of the front-surface terminal electrodes f may be configured such that an individual front-surface terminal electrode f is constituted only by an inspection pad p connected directly to a corresponding via conductor v.

FIG. 4 is a partial cross-sectional view taken along a line X-X in FIG. 3.

As shown in FIGS. 3 and 4, in the front-surface terminal electrodes f, the diameter d2 of the cover pad cp is greater than the diameter d1 of the inspection pad p. Further, the diameter d2 of the cover pad cp is at least 2.5 times the diameter d3 of the via conductor v connected to the bottom surface thereof. Incidentally, the diameter d1 of the inspection pad p is about 90 to 100 μm, and the pitch between adjacent inspection pads p is about 120 to 150 μm. Further, the diameter d2 of the cover pad cp is about 150 to 210 μm, and the diameter d3 of the via conductor v is about 70 to 85 μm.

Therefore, even in the case where the substrate body 1 having a plurality of unit inspection patterns a1 on the front surface 2 shrinks during a firing process in which a plurality of stacked green sheets are fired so as to form the above-described ceramic layers s1 to s8, reliable connection can be established between the via conductors v and the cover pads cp. Such reliable connection can be established not only in the unit inspection patterns a1 located at a central portion of the substrate body 1 as viewed from above the front surface of the substrate body, but also in the unit inspection patterns a1 located at a peripheral portion of the substrate body 1.

As a result, as shown in FIG. 1 mentioned above, current, supplied from the back-surface pads 9 on the back surface 3 of the substrate body 1 is fed to the inspection pads p by way of the via conductors v and V, the lands 10, and the wiring layers 5 to 8, via the cover pads cp and the connection wiring traces 4. The current is supplied to the terminal electrodes m of each to-be-inspected electronic component cn of the Si wafer W via the probes P attached to the inspection pad p, and is then supplied to the interior of the electronic component cn.

Meanwhile, inspection signals detected from the terminal electrodes m of individual ones of the to-be-inspected electronic components cn are returned to the back-surface pads 9 on the back surface 3 of the substrate body 1 via a route different from the above-described route, and then sent from the back-surface pads 9 to an external measurement apparatus (not shown).

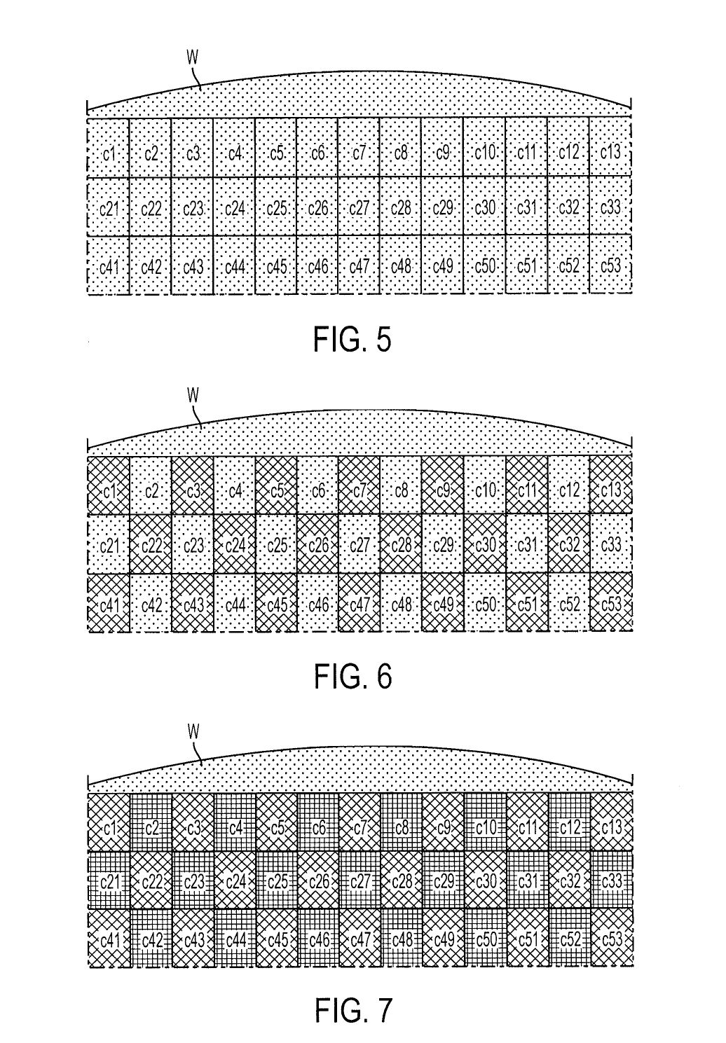

FIGS. 5 to 7 are schematic views showing the steps of an inspection performed by making use of the third wiring substrate K carrying the probes P attached to the inspection pads p.

As shown in FIG. 5, a large number of electronic components c1 to c53 are formed on the surface of the Si wafer W in a grid-like pattern (lattice pattern) such that the electronic components c1 to c53 are located adjacent to each other in the vertical and horizontal directions. First, as indicated by skewed cross hatchings in FIG. 6, electronic components c1, c3, . . . c53 which have odd numbers are simultaneously inspected by means of the plurality of unit inspection patterns a1, which are arranged on the wiring substrate K in the above-described arrangement pattern. Subsequently, as indicated by vertical and horizontal cross hatchings in FIG. 7, electronic components c2, c4, . . . c52 which have even numbers are simultaneously inspected by means of the plurality of unit inspection patterns a1 on the wiring substrate K, which have been moved in the horizontal direction by a distance generally corresponding to the width of the unit inspection patterns a1.

The large number of electronic components c1 to cn formed on the Si wafer W can be inspected accurately and efficiently, by repeatedly moving the wiring substrate K along the horizontal direction or the vertical direction.

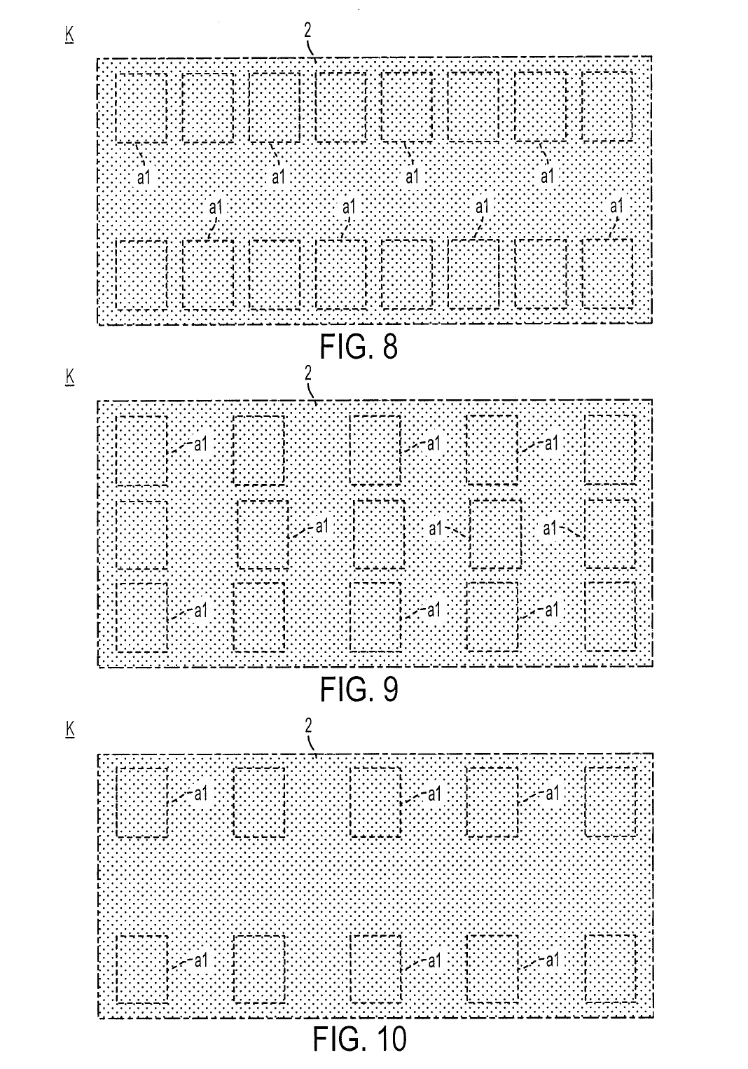

FIG. 8 is a partial plan view showing a mode of arrangement of the unit inspection patterns a1 on the front surface 2 of the substrate body 1 of a second wiring substrate K. As shown in FIG. 8, on the front surface 2, the plurality of unit inspection patterns a1 are shifted in the vertical direction from a grid-like arrangement (lattice pattern arrangement) as viewed from above such that a space corresponding to a horizontal row of unit inspection patterns a1 is provided between two vertically adjacent horizontal rows of unit inspection patterns.a1 Therefore, in respective unit inspection patterns a1, inspection pads p are disposed along a pair of shorter sides facing each other in the vertical direction such that the inspection pads p are located on the inner sides of the shorter sides of the inspection patterns a1; cover pads cp are disposed along the pair of shorter sides such that the inspection pads p are located on the outer sides of the shorter sides; and the inspection pads p and the cover pads cp are connected by connection wiring traces 4 which cross the shorter sides. Notably, in the vicinity of a pair of longer sides of the unit inspection pattern a1 facing each other in the horizontal direction, one or both of the above-described arrangement and an arrangement in which the entire front-surface terminal electrodes f are disposed inside the pattern a1 may be mixedly employed.

According to the second wiring substrate K having the arrangement mode shown in FIG. 8, the large number of electronic components cn formed on the Si wafer W can be inspected accurately and efficiently, by moving the wiring substrate K (in relation to the large number of electronic components cn formed on the Si wafer W) in the vertical direction over a distance corresponding to the horizontal row of unit inspection patterns a1.

FIG. 9 is a partial plan view showing a different mode of arrangement of the unit inspection patterns a1 on the second wiring substrate K. As shown in FIG. 9, on the front surface 2 of the wiring substrate K, the plurality of unit inspection patterns a1 are shifted in the horizontal direction from a grid-like arrangement (lattice pattern arrangement) as viewed from above such that a space corresponding to a vertical row of unit inspection patterns a1 is provided between two horizontally adjacent vertical rows of unit inspection patterns a1. Therefore, in respective unit inspection patterns a1, inspection pads p are disposed along a pair of longer sides facing each other in the horizontal direction such that the inspection pads p are located on the inner sides of the longer sides of the unit inspection patterns a1; cover pads cp are disposed along the pair of longer sides such that the inspection pads p are located on the outer sides of the longer sides; and the pads p and the cover pads cp are connected by connection wiring traces 4 which cross the longer sides. Notably, in the vicinity of a pair of shorter sides of the unit inspection pattern a1 facing each other in the vertical direction, one or both of the above-described arrangement and an arrangement in which the entire front-surface terminal electrodes f are disposed inside the unit inspection pattern a1 can be mixedly employed.

According to the second wiring substrate K having the arrangement mode shown in FIG. 9, a large number of electronic components cn formed on the Si wafer W can be inspected accurately and efficiently, by moving the wiring substrate K (in relation to the large number of electronic components cn formed on the Si wafer W) in the horizontal direction over a distance corresponding to the vertical row of unit inspection patterns a1.

FIG. 10 is a partial plan view showing another different mode of arrangement of the unit inspection patterns a1 on the second wiring substrate K. As shown in FIG. 10, on the front surface 2, the plurality of unit inspection patterns a1 are shifted in the vertical and horizontal directions from a grid-like arrangement (lattice pattern arrangement) as viewed from above such that a space corresponding to the horizontal row of unit inspection patterns a1 is provided between two vertically adjacent horizontal rows of unit inspection patterns a1, and a space corresponding to the vertical row of unit inspection patterns a1 is provided between two horizontally adjacent vertical rows of unit inspection patterns a1. Therefore, in each unit inspection pattern a1, inspection pads p are disposed along four sides of the unit inspection patterns a1 such that the inspection pads p are located on corresponding inner sides; cover pads cp are disposed along the four sides such that the inspection pads p are located on corresponding outer sides; and the pads p and the cover pads cp are connected by connection wiring traces 4. Notably, some of the front-surface terminal electrodes f may be disposed inside the unit inspection pattern a1.

According to the second wiring substrate K having the arrangement mode shown in FIG. 10, a large number of electronic components cn formed on the Si wafer W can be inspected accurately and efficiently, by performing the inspection after moving the wiring substrate K in the vertical direction or the horizontal direction (in relation to the large number of electronic components cn formed on the Si wafer W) over a distance corresponding to the horizontal row of unit inspection patterns a1 or the vertical row of unit inspection patterns a1, and again performing the inspection after moving the wiring substrate K in the horizontal direction or the vertical direction in the same manner.

FIG. 11 is a partial plan view showing a mode of arrangement of the unit inspection patterns a1 on the front surface 2 of the substrate body 1 of the first wiring substrate K. As shown in FIG. 11, on the front surface 2 of the substrate body 1, the plurality of unit inspection patterns a1 are shifted in the vertical direction from a grid-like arrangement (lattice pattern arrangement) as viewed from above such that horizontally adjacent unit inspection patterns a1 are shifted from each other in the vertical direction by an amount corresponding to about half the length of the longer sides thereof. Therefore, cover pads cp are disposed in respective unit inspection pattern a1, along the paired shorter sides and portions of the paired longer sides, the portions not being close to horizontally adjacent different unit inspection patterns a1, and the inspection pads p and the cover pads cp are connected by connection wiring traces 4. Notably, some of the front-surface terminal electrodes f may be disposed such that the entirety of each front-surface terminal electrode f is located inside the unit inspection pattern a1.

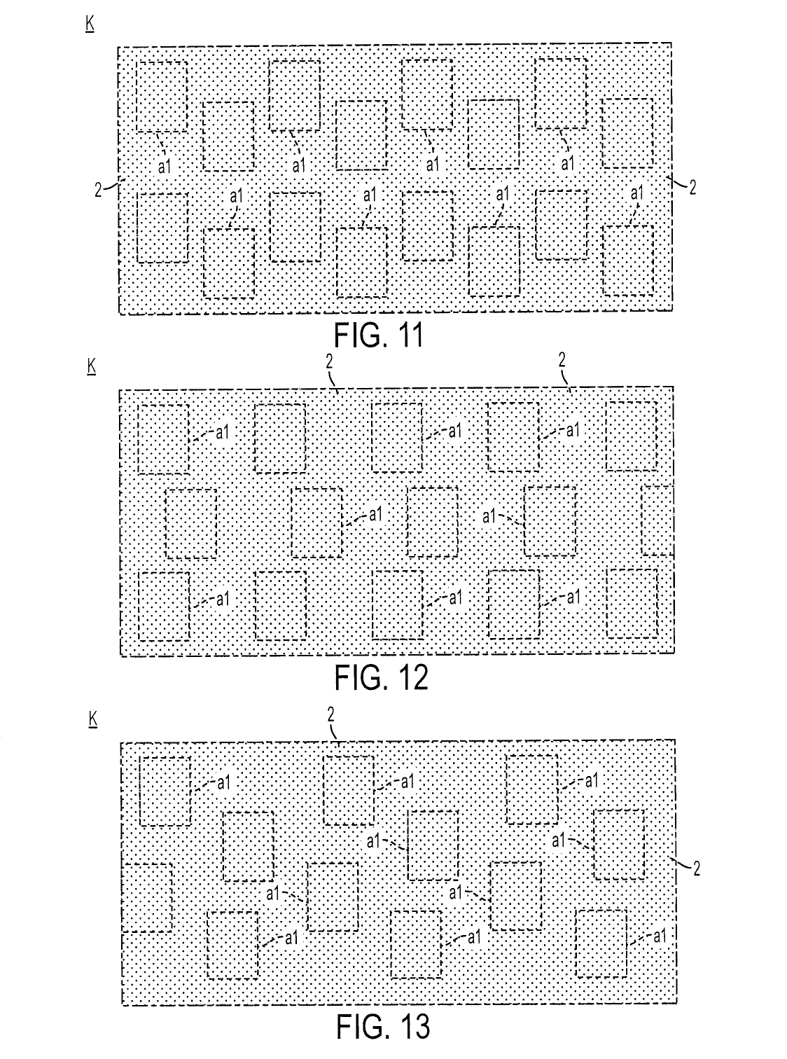

FIG. 12 is a partial plan view showing a different mode of arrangement of the unit inspection patterns a1 of the first wiring substrate K. As shown in FIG. 12, on the front surface 2 of the substrate body 1, the plurality of unit inspection patterns a1 are shifted in the horizontal direction from a grid-like arrangement (lattice pattern arrangement) as viewed from above such that vertically adjacent unit inspection patterns a1 are shifted from each other in the horizontal direction by an amount corresponding to about half the length of the shorter sides thereof. Therefore, cover pads cp are disposed in respective unit inspection pattern a1, along the paired longer sides and portions of the paired shorter sides, the portions not being close to vertically adjacent different unit inspection patterns a1, and the inspection pads p and the cover pads cp are connected by the connection wiring traces 4.

FIG. 13 is a partial plan view showing another different mode of arrangement of the unit inspection patterns a1 on the first wiring substrate K. As shown in FIG. 12, on the front surface 2 of the substrate body 1, the plurality of unit inspection patterns a1 are shifted in the vertical and horizontal directions from a grid-like arrangement (lattice pattern arrangement) as viewed from above such that vertically or horizontally adjacent unit inspection patterns a1 are shifted from each other in the horizontal direction or the vertical direction by an amount less than half the length of the longer sides or shorter sides thereof. Therefore, cover pads cp are disposed in respective unit inspection pattern a1 along all four sides thereof, and the inspection pads p and the cover pads cp are connected by connection wiring traces 4.

Even when the first wiring substrate K having the above-described arrangement mode is employed, a large number of electronic components cn on the Si wafer W can be inspected accurately and efficiently, by alternately performing the inspection and an operation of properly shifting the substrate body 1 in the vertical direction or the horizontal direction in relation to the large number of electronic components cn formed on the Si wafer W.

The present invention is not limited to the above-described embodiments.

For example, the configuration of the substrate body is not particularly limited, so long as the substrate body is formed by stacking at least two ceramic layers.

Further, in accordance with the arrangement of a plurality of terminal electrodes of each electronic component to be inspected, the unit inspection pattern may assume, as viewed from above, a square shape, a near-square shape, a regular polygonal shape (e.g., hexagonal shape), a modified polygonal shape, a circular shape, an oval shape, an elliptical shape, or a like shape.

Moreover, the shapes of the inspection pads and the cover pads are not limited to the above-described circular shape as viewed from above, and the inspection pads and the cover pads may assume the shape of a regular polygon or a polygon with rounded corners.

It should further be apparent to those skilled in the art that various changes in form and detail of the invention as shown and described above may be made. It is intended that such changes be included within the spirit and scope of the claims appended hereto.

This application is based on Japanese Patent Application No. JP 2008-23722 filed Feb. 4, 2008, incorporated herein by reference in its entirety.

What is claimed is:

1. A wiring substrate for an electronic-component inspection apparatus comprising:
a substrate body composed of a plurality of stacked ceramic layers, said substrate body having a front surface and a back surface; and
front-surface terminal electrodes formed on the front surface of the substrate body, and grouped into unit inspection patterns, individual ones of the unit inspection patterns being constituted by a plurality of the front-surface terminal electrodes disposed so as to correspond to a plurality of terminal electrodes of individual electronic components to be inspected,
wherein said unit inspection patterns are disposed so as to be offset distance-wise from a lattice arrangement in at least one of orthogonal first and second directions, as viewed from above the front surface of the substrate body.

2. A wiring substrate for an electronic-component inspection apparatus comprising:
a substrate body composed of a plurality of stacked ceramic layers, said substrate body having a front surface and a back surface; and
front-surface terminal electrodes formed on the front surface of the substrate body, and grouped into unit inspection patterns, individual ones of the unit inspection patterns being constituted by a plurality of the front-surface terminal electrodes disposed so as to correspond to a plurality of terminal electrodes of individual electronic components to be inspected,
wherein said unit inspection patterns are disposed so as to be offset distance-wise from a lattice arrangement of rows and columns in at least one of orthogonal first and second directions, as viewed from above the front surface of the substrate body, wherein the unit inspection patterns are arranged in every other row but not in alternate rows in at least one of the first and second directions.

3. A wiring substrate for an electronic-component inspection apparatus comprising:
a substrate body composed of a plurality of stacked ceramic layers, said substrate body having a front surface and a back surface; and
front-surface terminal electrodes formed on the front surface of the substrate body, and grouped into unit inspection patterns, individual ones of the unit inspection patterns being constituted by a plurality of the front-surface terminal electrodes disposed so as to correspond to a plurality of terminal electrodes of individual electronic components to be inspected,
wherein said unit inspection patterns are regularly arranged in orthogonal first and second directions, as viewed from above the front surface of the substrate body, such that centroids of the respective unit inspection patterns coincide with alternate ones of intersections between first imaginary lines and second imaginary lines extending along the first and second directions, respectively, and passing through the centroids of the unit inspection patterns.

4. The wiring substrate for an electronic-component inspection apparatus according to claim 1, wherein some of the front-surface terminal electrodes each includes at least an inspection pad formed inside an associated unit inspection pattern, a cover pad connected to a via conductor exposed to the front surface of the substrate body, and a connection wiring trace which connects the inspection pad and the cover pad.

5. The wiring substrate for an electronic-component inspection apparatus according to claim 2, wherein some of the front-surface terminal electrodes each includes at least an inspection pad formed inside an associated unit inspection pattern, a cover pad connected to a via conductor exposed to the front surface of the substrate body, and a connection wiring trace which connects the inspection pad and the cover pad.

6. The wiring substrate for an electronic-component inspection apparatus according to claim 3, wherein some of the front-surface terminal electrodes each includes at least an inspection pad formed inside an associated unit inspection pattern, a cover pad connected to a via conductor exposed to the front surface of the substrate body, and a connection wiring trace which connects the inspection pad and the cover pad.

7. The wiring substrate for an electronic-component inspection apparatus according to claim 4, wherein individual ones of the unit inspection patterns have a rectangular shape as viewed from above the front surface of the substrate body; a plurality of inspection pads are formed along all sides of respective unit inspection patterns; cover pads individually connected to the inspection pads via dedicated connection wiring traces are formed in an area surrounded by the inspection pads associated with an unit inspection pattern or outside an associated unit inspection pattern; and the cover pads are connected to via conductors which pass through at least an uppermost ceramic layer which forms the front surface of the substrate body.

8. The wiring substrate for an electronic-component inspection apparatus according to claim 5, wherein individual ones of the unit inspection patterns have a rectangular shape as viewed from above the front surface of the substrate body; a plurality of inspection pads are formed along all sides of respective unit inspection patterns; cover pads individually connected to the inspection pads via dedicated connection wiring traces are formed in an area surrounded by the inspection pads associated with an unit inspection pattern or outside an associated unit inspection pattern; and the cover pads are connected to via conductors which pass through at least an uppermost ceramic layer which forms the front surface of the substrate body.

9. The wiring substrate for an electronic-component inspection apparatus according to claim 6, wherein individual ones of the unit inspection patterns have a rectangular shape as viewed from above the front surface of the substrate body; a plurality of inspection pads are formed along all sides of respective unit inspection patterns; cover pads individually connected to the inspection pads via dedicated connection wiring traces are formed in an area surrounded by the inspection pads associated with an unit inspection pattern or outside an associated unit inspection pattern; and the cover pads are connected to via conductors which pass through at least an uppermost ceramic layer which forms the front surface of the substrate body.

10. The wiring substrate for an electronic-component inspection apparatus according to claim 4, wherein the cover pads are larger than the inspection pads.

11. The wiring substrate for an electronic-component inspection apparatus according to claim 5, wherein the cover pads are larger than the inspection pads.

12. The wiring substrate for an electronic-component inspection apparatus according to claim 6, wherein the cover pads are larger than the inspection pads.

13. The wiring substrate for an electronic-component inspection apparatus according to claim 4, wherein the cover pads are larger in diameter than the via conductors to which the cover pads are connected.

14. The wiring substrate for an electronic-component inspection apparatus according to claim 5, wherein the cover pads are larger in diameter than the via conductors to which the cover pads are connected.

15. The wiring substrate for an electronic-component inspection apparatus according to claim 6, wherein the cover pads are larger in diameter than the via conductors to which the cover pads are connected.

16. The wiring substrate for an electronic-component inspection apparatus according to claim 4, wherein the diameter of the cover pads is at least 2.5 times the diameter of the via conductors.

17. The wiring substrate for an electronic-component inspection apparatus according to claim 5, wherein the diameter of the cover pads is at least 2.5 times the diameter of the via conductors.

18. The wiring substrate for an electronic-component inspection apparatus according to claim 6, wherein the diameter of the cover pads is at least 2.5 times the diameter of the via conductors.
